(19) United States
(12) Patent Application Publication
(10) Pub. No.: US 2026/0136561 A1
(43) Pub. Date: May 14, 2026

(54) MAGNETIC MEMORY STRUCTURE

(71) Applicant: Powerchip Semiconductor Manufacturing Corporation, Hsinchu (TW)

(72) Inventor: Zih-Song Wang, Nantou County (TW)

(73) Assignee: Powerchip Semiconductor Manufacturing Corporation, Hsinchu (TW)

(21) Appl. No.: 19/045,464

(22) Filed: Feb. 4, 2025

(30) Foreign Application Priority Data
Nov. 11, 2024 (TW) 113143229

(51) Int. Cl. H10B 61/00; H10N 50/10; H10N 50/80; H10N 50/85

(52) U.S. Cl. CPC H10B 61/10; H10N 50/10; H10N 50/80; H10N 50/85

(57) ABSTRACT

A magnetic memory structure including the following components is provided. A second reference layer is located on a first reference layer. A data storage free layer is located between the first reference layer and the second reference layer. A first switching accelerator free layer is located between the data storage free layer and the first reference layer. A second switching accelerator free layer is located between the data storage free layer and the second reference layer. A first barrier layer is located between the first switching accelerator free layer and the first reference layer. A second barrier layer is located between the second switching accelerator free layer and the second reference layer. A first spacer layer is located between the data storage free layer and the first switching accelerator free layer. A second spacer layer is located between the data storage free layer and the second switching accelerator free layer.

### CROSS-REFERENCE TO RELATED APPLICATION

This application claims the priority benefit of Taiwan application serial no. 113143229, filed on Nov. 11, 2024. The entirety of the above-mentioned patent application is hereby incorporated by reference herein and made a part of this specification.

### BACKGROUND

### Technical Field

The invention relates to a memory structure, and particularly relates to a magnetic memory structure.

### Description of Related Art

The magnetic memory has attracted more and more attention due to its advantages such as fast reading and writing speed, excellent durability, non-volatility and low power consumption. However, how to further improve the electrical performance of the magnetic memory is the goal of continuous efforts.

### SUMMARY

The invention provides a magnetic memory structure, which can effectively improve the electrical performance of the magnetic memory.

The invention provides a magnetic memory structure, which includes a first reference layer, a second reference layer, a data storage free layer, a first switching accelerator free layer, a second switching accelerator free layer, a first barrier layer, a second barrier layer, a first spacer layer, and a second spacer layer. The second reference layer is located on the first reference layer. The data storage free layer is located between the first reference layer and the second reference layer. The first switching accelerator free layer is located between the data storage free layer and the first reference layer. The second switching accelerator free layer is located between the data storage free layer and the second reference layer. The first barrier layer is located between the first switching accelerator free layer and the first reference layer. The second barrier layer is located between the second switching accelerator free layer and the second reference layer. The first spacer layer is located between the data storage free layer and the first switching accelerator free layer. The second spacer layer is located between the data storage free layer and the second switching accelerator free layer.

According to an embodiment of the invention, in the magnetic memory structure, the shape of the first reference layer, the shape of the data storage free layer, the shape of the first switching accelerator free layer, the shape of the second switching accelerator free layer, the shape of the first barrier layer, the shape of the second barrier layer, the shape of the first spacer layer, and the shape of the second spacer layer may be column shapes.

According to an embodiment of the invention, in the magnetic memory structure, the shape of the second reference layer may be a strip shape or a column shape.

According to an embodiment of the invention, in the magnetic memory structure, the material of the first reference layer is, for example, an alloy of at least two selected from a group consisting of cobalt (Co), iridium (Ir), platinum (Pt), nickel (Ni), chromium (Cr), and iron (Fe).

According to an embodiment of the invention, in the magnetic memory structure, the material of the second reference layer is, for example, an alloy of at least two selected from a group consisting of cobalt, iridium, platinum, nickel, chromium, and iron.

According to an embodiment of the invention, in the magnetic memory structure, the first reference layer and the second reference layer may have opposite magnetic directions.

According to an embodiment of the invention, in the magnetic memory structure, the material of the data storage free layer is, for example, cobalt-platinum (CoPt) or nickel-iron (NiFe).

According to an embodiment of the invention, in the magnetic memory structure, the material of the first switching accelerator free layer is, for example, cobalt-iron-boron (CoFeB).

According to an embodiment of the invention, in the magnetic memory structure, the material of the second switching accelerator free layer is, for example, cobalt-iron-boron.

According to an embodiment of the invention, in the magnetic memory structure, the material of the first barrier layer is, for example, magnesium oxide (MgO).

According to an embodiment of the invention, in the magnetic memory structure, the material of the second barrier layer is, for example, magnesium oxide.

According to an embodiment of the invention, in the magnetic memory structure, the material of the first spacer layer is, for example, ruthenium (Ru), tantalum (Ta), or tungsten (W).

According to an embodiment of the invention, in the above magnetic memory structure, the material of the second spacer layer is, for example, ruthenium, tantalum, or tungsten.

According to an embodiment of the invention, the magnetic memory structure may further include a first conductive layer and a second conductive layer. The first reference layer is located on the first conductive layer. The second conductive layer is located on the second reference layer.

According to an embodiment of the invention, in the magnetic memory structure, the first conductive layer may be in direct contact with the first reference layer.

According to an embodiment of the invention, in the magnetic memory structure, the second conductive layer may be in direct contact with the second reference layer.

According to an embodiment of the invention, in the magnetic memory structure, the second conductive layer and the second reference layer may extend in the same direction.

According to an embodiment of the invention, in the magnetic memory structure, the shape of the first conductive layer and the shape of the second conductive layer may be strip shapes.

According to an embodiment of the invention, in the magnetic memory structure, the material of the first conductive layer is, for example, copper (Cu), aluminum (Al), tungsten (W), tantalum (Ta), tantalum nitride (TaN), titanium (Ti), titanium nitride (TiN), or a combination thereof.

According to an embodiment of the invention, in the magnetic memory structure, the material of the second conductive layer is, for example, copper, aluminum, tungsten, tantalum, tantalum nitride, titanium, titanium nitride, or a combination thereof.

Based on the above description, in the magnetic structure memory according to the invention, the second reference layer is located on the first reference layer. The data storage free layer is located between the first reference layer and the second reference layer. The first switching accelerator free layer is located between the data storage free layer and the first reference layer. The second switching accelerator free layer is located between the data storage free layer and the second reference layer. The first barrier layer is located between the first switching accelerator free layer and the first reference layer. The second barrier layer is located between the second switching accelerator free layer and the second reference layer. The first spacer layer is located between the data storage free layer and the first switching accelerator free layer. The second spacer layer is located between the data storage free layer and the second switching accelerator free layer. Therefore, the first reference layer, the first barrier layer, the first switching accelerator free layer, and first spacer layer located on one side of the data storage free layer and the second reference layer, the second barrier layer, the second switching accelerator free layer, and the second spacer layer located on the other side of the data storage free layer can be arranged symmetrically relative to the data storage free layer. In this way, the speed of writing data “1” in the magnetic memory structure can be the same as the speed of writing data “0” in the magnetic memory structure, so the magnetic memory structure can have better data retention capacity and can reduce the interference of the stray field.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a perspective view of a magnetic memory structure according to some embodiments of the invention.

FIG. 2 is a perspective view of a magnetic memory structure according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

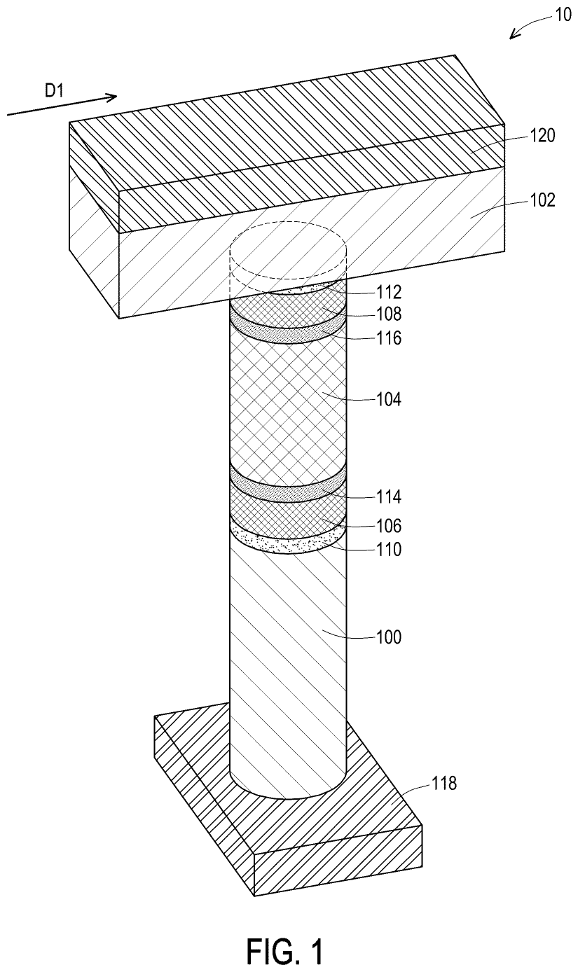

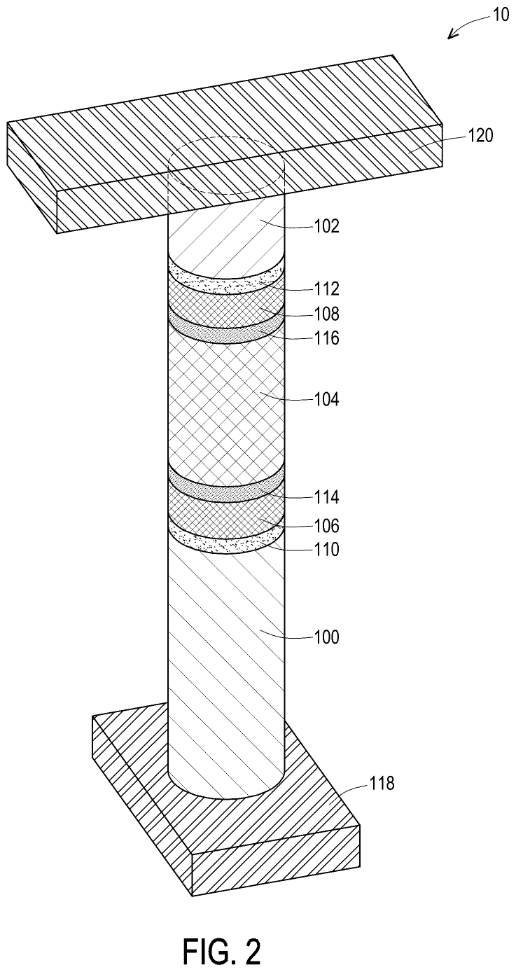

FIG. 1 is a perspective view of a magnetic memory structure according to some embodiments of the invention. FIG. 2 is a perspective view of a magnetic memory structure according to other embodiments of the invention.

Referring to FIG. 1, a magnetic memory structure 10 includes a reference layer 100, a reference layer 102, a data storage free layer 104, a switching accelerator free layer 106, a switching accelerator free layer 108, a barrier layer 110, a barrier layer 112, a spacer layer 114, and a spacer layer. 116. In addition, although not shown in the figure, the magnetic memory structure 10 may further include other required components (e.g., a substrate and/or a dielectric layer), and the description thereof is omitted here. In some embodiments, the magnetic memory structure 10 may be a perpendicular shape anisotropy (PSA)-spin transfer torque (STT)-magnetic random access memory (MRAM) (PSA-STT-MRAM). In some embodiments, the shape of the reference layer 100 may be a column shape such as a cylindrical shape. In some embodiments, the material of the reference layer 100 may be a synthetic antiferromagnetic (SAF) material. In some embodiments, the material of the reference layer 100 is, for example, an alloy of at least two selected from a group consisting of cobalt, iridium, platinum, nickel, chromium, and iron. In some embodiments, the material of the reference layer 100 is, for example, CoPt, CoIr, NiCr, CrFe, or Ru.

The reference layer 102 is located on the reference layer 100. In some embodiments, the reference layer 100 and the reference layer 102 may have opposite magnetic directions. In the present embodiment, as shown in FIG. 1, the shape of the reference layer 102 may be a strip shape. In other embodiments, as shown in FIG. 2, the shape of the reference layer 102 may be a column shape such as a cylindrical shape. In some embodiments, the material of the reference layer 102 may be a synthetic antiferromagnetic material. In some embodiments, the material of the reference layer 102 is, for example, an alloy of at least two selected from a group consisting of cobalt, iridium, platinum, nickel, chromium, and iron. In some embodiments, the material of the reference layer 102 is, for example, CoPt, CoIr, NiCr, CrFe, or Ru.

The data storage free layer 104 is located between the reference layer 100 and the reference layer 102. Compared with the switching accelerator free layer 106 and the switching accelerator free layer 108, the data storage free layer 104 may have better data retention capacity. In some embodiments, the shape of the data storage free layer 104 may be a column shape such as a cylindrical shape. In some embodiments, the material of the data storage free layer 104 is, for example, cobalt-platinum or nickel-iron.

The switching accelerator free layer 106 is located between the data storage free layer 104 and the reference layer 100. In some embodiments, the shape of the switching accelerator free layer 106 may be a column shape such as a cylindrical shape. In some embodiments, the material of the switching accelerator free layer 106 is, for example, cobalt-iron-boron.

The switching accelerator free layer 108 is located between the data storage free layer 104 and the reference layer 102. In some embodiments, the shape of the switching accelerator free layer 108 may be a column shape such as a cylindrical shape. In some embodiments, the material of the switching accelerator free layer 108 is, for example, cobalt-iron-boron.

The barrier layer 110 is located between the switching accelerator free layer 106 and the reference layer 100. In some embodiments, the barrier layer 110 may be a column shape such as a cylindrical shape. In some embodiments, the material of the barrier layer 110 is, for example, magnesium oxide.

The barrier layer 112 is located between the switching accelerator free layer 108 and the reference layer 102. In some embodiments, the barrier layer 112 may be a column shape such as a cylindrical shape. In some embodiments, the material of the barrier layer 112 is, for example, magnesium oxide.

The spacer layer 114 is located between the data storage free layer 104 and the switching accelerator free layer 106. In some embodiments, the shape of the spacer layer 114 may be a column shape such as a cylindrical shape. In some embodiments, the material of the spacer layer 114 is, for example, ruthenium, tantalum, or tungsten.

The spacer layer 116 is located between the data storage free layer 104 and the switching accelerator free layer 108. In some embodiments, the shape of the spacer layer 116 may be a column shape such as a cylindrical shape. In some embodiments, the material of the spacer layer 116 is, for example, ruthenium, tantalum, or tungsten.

The magnetic memory structure 10 may further include a conductive layer 118 and a conductive layer 120. In some embodiments, the conductive layer 118 may be used as a word line, and the conductive layer 120 may be used as a bit line. In other embodiments, the conductive layer 118 may be used as a bit line, and the conductive layer 120 may be used as a word line.

The reference layer 100 is located on the conductive layer 118. In some embodiments, the conductive layer 118 may be in direct contact with the reference layer 100. In some embodiments, the shape of the conductive layer 118 may be a strip shape. In some embodiments, the material of the conductive layer 118 is, for example, copper, aluminum, tungsten, tantalum, tantalum nitride, titanium, titanium nitride, or a combination thereof.

The conductive layer 120 is located on the reference layer 102. In some embodiments, the conductive layer 120 may be in direct contact with the reference layer 102. In some embodiments, as shown in FIG. 1, the conductive layer 120 and the reference layer 102 may extend in the same direction (e.g., direction D1). In some embodiments, the shape of the conductive layer 120 may be a strip shape. In some embodiments, the material of the conductive layer 120 is, for example, copper, aluminum, tungsten, tantalum, tantalum nitride, titanium, titanium nitride, or a combination thereof.

Based on the above embodiments, in the magnetic structure memory 10, the reference layer 102 is located on the reference layer 100. The data storage free layer 104 is located between the reference layer 100 and the reference layer 102. The switching accelerator free layer 106 is located between the data storage free layer 104 and the reference layer 100. The switching accelerator free layer 108 is located between the data storage free layer 104 and the reference layer 102. The barrier layer 110 is located between the switching accelerator free layer 106 and the reference layer 100. The barrier layer 112 is located between the switching accelerator free layer 108 and the reference layer 102. The spacer layer 114 is located between the data storage free layer 104 and the switching accelerator free layer 106. The spacer layer 116 is located between the data storage free layer 104 and the switching accelerator free layer 108. Therefore, the reference layer 100, the barrier layer 110, the switching accelerator free layer 106, and the spacer layer 114 located on one side of the data storage free layer 104 and the reference layer 102, the barrier layer 112, the switching accelerator free layer 108, and the spacer layer 116 located on the other side of the data storage free layer 104 can be arranged symmetrically relative to the data storage free layer 104. In this way, the speed of writing data “1” in the magnetic memory structure 10 can be the same as the speed of writing data “0” in the magnetic memory structure 10, so the magnetic memory structure 10 can have better data retention capacity and can reduce the interference of the stray field.

In summary, in the magnetic memory structure of the aforementioned embodiments, the second reference layer is located on the first reference layer. The data storage free layer is located between the first reference layer and the second reference layer. The first switching accelerator free layer is located between the data storage free layer and the first reference layer. The second switching accelerator free layer is located between the data storage free layer and the second reference layer. The first barrier layer is located between the first switching accelerator free layer and the first reference layer. The second barrier layer is located between the second switching accelerator free layer and the second reference layer. The first spacer layer is located between the data storage free layer and the first switching accelerator free layer. The second spacer layer is located between the data storage free layer and the second switching accelerator free layer. Therefore, the first reference layer, the first barrier layer, the first switching accelerator free layer, and first spacer layer located on one side of the data storage free layer and the second reference layer, the second barrier layer, the second switching accelerator free layer, and the second spacer layer located on the other side of the data storage free layer can be arranged symmetrically relative to the data storage free layer. In this way, the speed of writing data “1” in the magnetic memory structure can be the same as the speed of writing data “0” in the magnetic memory structure, so the magnetic memory structure can have better data retention capacity and can reduce the interference of the stray field.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A magnetic memory structure, comprising:
a first reference layer;
a second reference layer located on the first reference layer;
a data storage free layer located between the first reference layer and the second reference layer;
a first switching accelerator free layer located between the data storage free layer and the first reference layer;
a second switching accelerator free layer located between the data storage free layer and the second reference layer;
a first barrier layer located between the first switching accelerator free layer and the first reference layer;
a second barrier layer located between the second switching accelerator free layer and the second reference layer;
a first spacer layer located between the data storage free layer and the first switching accelerator free layer; and
a second spacer layer located between the data storage free layer and the second switching accelerator free layer.

2. The magnetic memory structure according to claim 1, wherein a shape of the first reference layer, a shape of the data storage free layer, a shape of the first switching accelerator free layer, a shape of the second switching accelerator free layer, a shape of the first barrier layer, a shape of the second barrier layer, a shape of the first spacer layer, and a shape of the second spacer layer comprise column shapes.

3. The magnetic memory structure according to claim 1, wherein a shape of the second reference layer comprises a strip shape or a column shape.

4. The magnetic memory structure according to claim 1, wherein a material of the first reference layer comprises an alloy of at least two selected from a group consisting of cobalt, iridium, platinum, nickel, chromium, and iron.

5. The magnetic memory structure according to claim 1, wherein a material of the second reference layer comprises an alloy of at least two selected from a group consisting of cobalt, iridium, platinum, nickel, chromium, and iron.

6. The magnetic memory structure according to claim 1, wherein the first reference layer and the second reference layer have opposite magnetic directions.

7. The magnetic memory structure according to claim 1, wherein a material of the data storage free layer comprises cobalt-platinum or nickel-iron.

8. The magnetic memory structure according to claim 1, wherein a material of the first switching accelerator free layer comprises cobalt-iron-boron.

9. The magnetic memory structure according to claim 1, wherein a material of the second switching accelerator free layer comprises cobalt-iron-boron.

10. The magnetic memory structure according to claim 1, wherein a material of the first barrier layer comprises magnesium oxide.

11. The magnetic memory structure according to claim 1, wherein a material of the second barrier layer comprises magnesium oxide.

12. The magnetic memory structure according to claim 1, wherein a material of the first spacer layer comprises ruthenium, tantalum, or tungsten.

13. The magnetic memory structure according to claim 1, wherein a material of the second spacer layer comprises ruthenium, tantalum, or tungsten.

14. The magnetic memory structure according to claim 1, further comprising:
a first conductive layer, wherein the first reference layer is located on the first conductive layer; and
a second conductive layer located on the second reference layer.

15. The magnetic memory structure according to claim 14, wherein the first conductive layer is in direct contact with the first reference layer.

16. The magnetic memory structure according to claim 14, wherein the second conductive layer is in direct contact with the second reference layer.

17. The magnetic memory structure according to claim 14, wherein the second conductive layer and the second reference layer extend in a same direction.

18. The magnetic memory structure according to claim 14, wherein a shape of the first conductive layer and a shape of the second conductive layer comprise strip shapes.

19. The magnetic memory structure according to claim 14, wherein a material of the first conductive layer comprises copper, aluminum, tungsten, tantalum, tantalum nitride, titanium, titanium nitride, or a combination thereof.

20. The magnetic memory structure according to claim 14, wherein a material of the second conductive layer comprises copper, aluminum, tungsten, tantalum, tantalum nitride, titanium, titanium nitride, or a combination thereof.
